(19) United States
(12) Patent Application Publication
(10) Pub. No.: US 2026/0300562 A1
(43) Pub. Date: Oct. 1, 2026

(54) AI-Driven Theoretical Testing (+AIdtt) System

(71) Applicant: Erik Micael Baum, BUENOS AIRES (AR)

(72) Inventor: Erik Micael Baum, BUENOS AIRES (AR)

(21) Appl. No.: 19/060,372

(22) Filed: Feb. 21, 2025

(51) Int. Cl. G06F 30/12; G06F 40/40

(52) U.S. Cl. CPC G06F 30/12; G06F 40/40

(57) ABSTRACT

The AI-Driven Theoretical Testing (+AIdtt) System is a comprehensive framework for automating theory-building. The system integrates AI-driven tools and a Model Rendering Algorithm to enable efficient, rigorous, and accessible theory building. Key components include FRaw for input validation, a Model Rendering Algorithm for generating initial models, and refinement tools such as Alfct, Alfemp, and Alfeth for iterative refinement. The system ensures that theoretical models are logically coherent, empirically grounded, and ethically sound, while significantly reducing the time and effort required for theory building.

### BACKGROUND OF THE INVENTION

The present invention relates to the field of artificial intelligence (Al) and, more specifically, to systems and methods for automated theory building and validation. Traditional approaches to theory building are often time-consuming, labor-intensive, and prone to human error. These limitations hinder the rapid development and refinement of robust theoretical frameworks across disciplines such as science, engineering, and social sciences.

Existing systems lack the ability to systematically validate theoretical models for logical consistency, empirical grounding, and ethical soundness. Furthermore, they do not provide tools for iterative refinement or user-friendly interaction through multi-modal interfaces, including but not limited to natural language, voice commands, and visual inputs. The +AIdtt system addresses these limitations by integrating AI-driven tools and a Model Rendering Algorithm to enable efficient, rigorous, and accessible theory building.

### BRIEF SUMMARY OF THE INVENTION

The AI-Driven Theoretical Testing (+AIdtt) System is a cutting-edge technological framework designed to revolutionize the process of theory building. The system comprises a plurality of interconnected tools, including FRaw, AIfit, AIfct, AIfemp, and others, which collectively enable the creation, testing, refinement, and validation of theoretical models.

Key features of the +AIdtt system include:

Input Validation (FRaw): Ensures the quality and relevance of inputs using natural language processing (NLP) and anomaly detection algorithms.

Model Rendering Algorithm: Generates initial models based on fragmented theoretical constituents.

Iterative Refinement: Enables continuous improvement of models through feedback from tools such as AIfct (consistency testing), AIfemp (empirical validation), and AIfeth (ethical analysis).

Multi-Modal Interface: Provides a user-friendly, interactive layer for discussing and refining models through natural language, voice commands, and visual inputs.

The +AIdtt system ensures that theoretical models are logically coherent, empirically grounded, and ethically sound, while significantly reducing the time and effort required for theory building.

### BRIEF DESCRIPTION OF THE DRAWINGS

The following figures illustrate the +AIdtt system and its components:

FIG. 1: FRaw (Input Validation), showing the process of validating raw inputs using NLP and anomaly detection algorithms.

FIG. 2: Basic Theoretical Constituents (Fragmentation), depicting the breakdown of validated inputs into axioms, hypotheses, and constraints.

FIG. 3: Model Rendering Algorithm, illustrating the generation of initial models based on fragmented constituents.

FIG. 4: AIfct (AI Framework Consistency Test), showing the process of testing internal consistency using formal logic systems.

FIG. 5: AIfcr (AI Framework Comparison Rendering), depicting the comparative analysis of different theoretical models.

FIG. 6: AIfemp (AI Framework Empirical Validation), illustrating the process of validating models against empirical data.

FIG. 7: AIfeth (AI Framework Ethical Implications), showing the detection and mitigation of ethical issues and biases.

FIG. 8: AIfit (AI Framework Integration Task), depicting the integration of new concepts into existing theoretical frameworks.

FIG. 9: AIfmeta (AI Framework Meta-Optimization), illustrating the optimization of the overall theory-building process.

FIG. 10: AIfsim (AI Framework Simulation), showing the simulation and prediction of model outcomes.

FIG. 11: AIfviz (AI Framework Visualization), depicting the generation of intuitive visual representations of theories.

FIG. 12: Actualize (Actualized Summary Rendering), illustrating the summarization and documentation of refined models.

FIG. 13: Iterative Refinement Feedback Loop, showing the recursive refinement process between tools and the Model Rendering Algorithm.

FIG. 14: Framework Workflow, depicting the end-to-end process of theory building.

FIG. 15: Multi-Modal Interface, illustrating the user interaction layer for discussing and refining models.

FIG. 16: External System Integration, showing the interaction between the +AIdtt system and external systems (e.g., CAD software, industrial machines, medical devices) for real-world validation and feasibility testing.

### DETAILED DESCRIPTION OF THE INVENTION

The AI-Driven Theoretical Testing (+AIdtt) System is a comprehensive framework for automating the theory-building process. The system integrates Al-driven tools and a Model Rendering Algorithm to enable efficient, rigorous, and accessible theory building.

### SYSTEM ARCHITECTURE

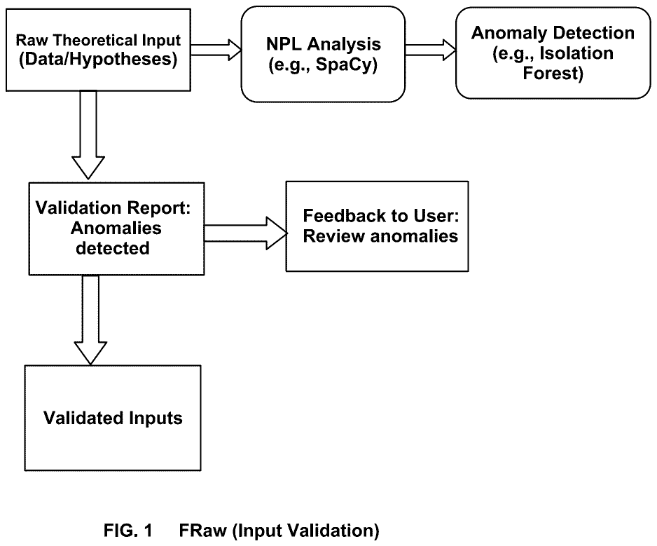

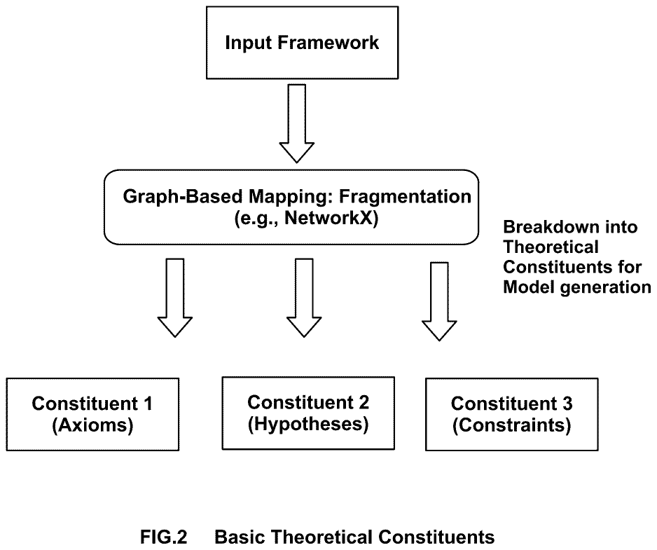

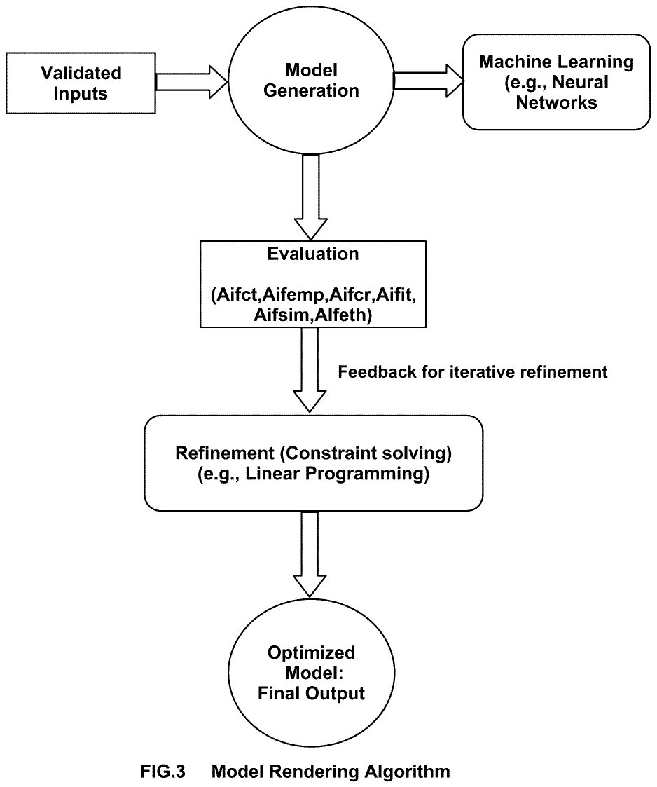

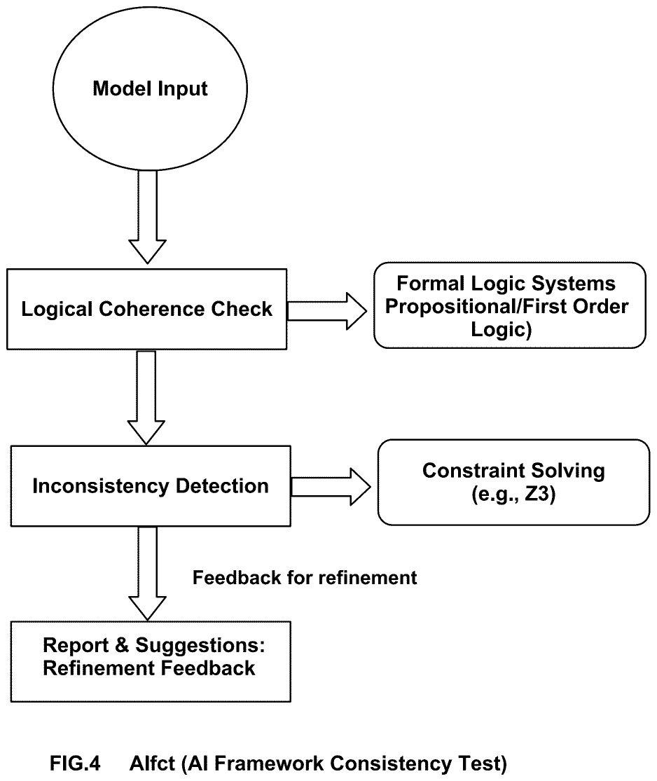

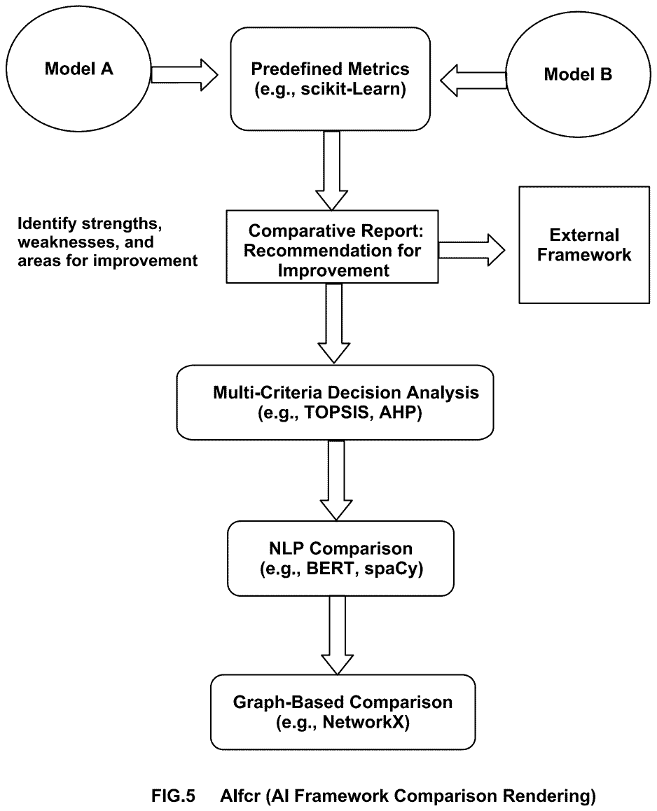

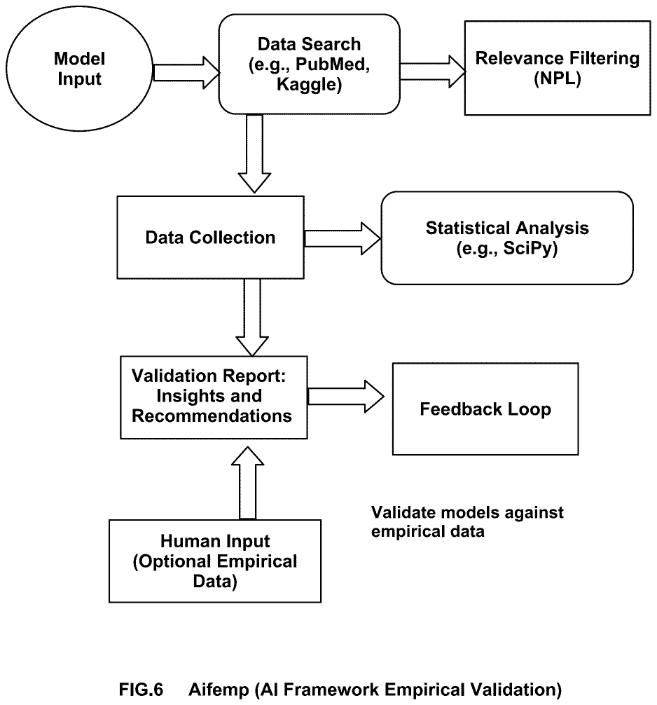

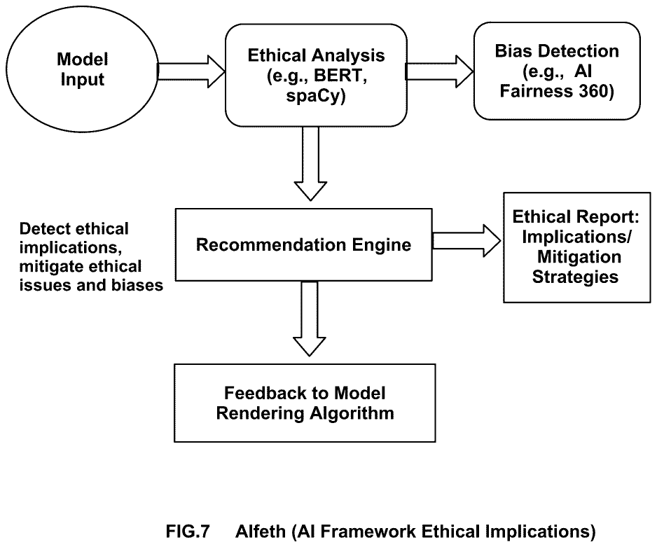

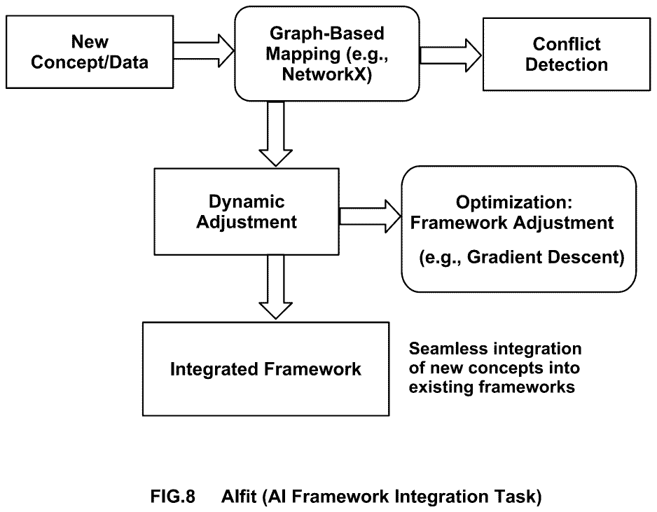

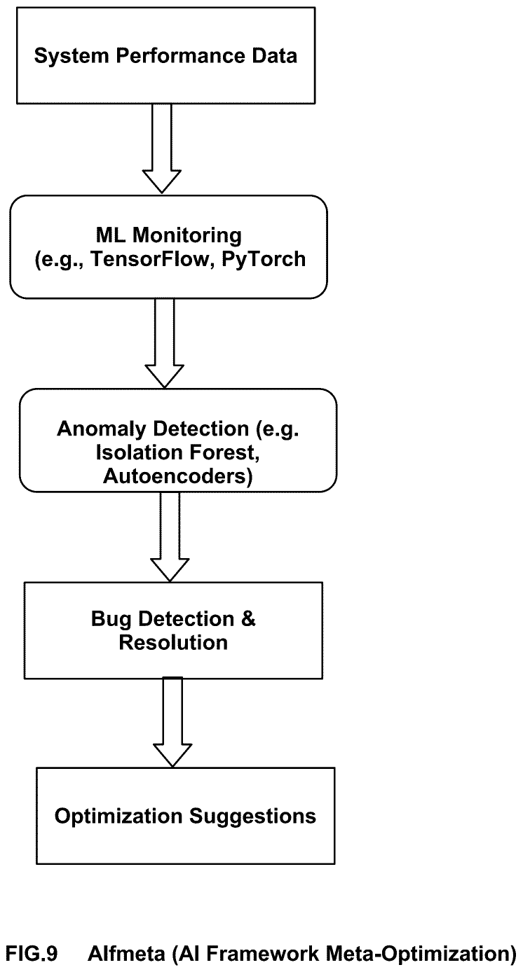

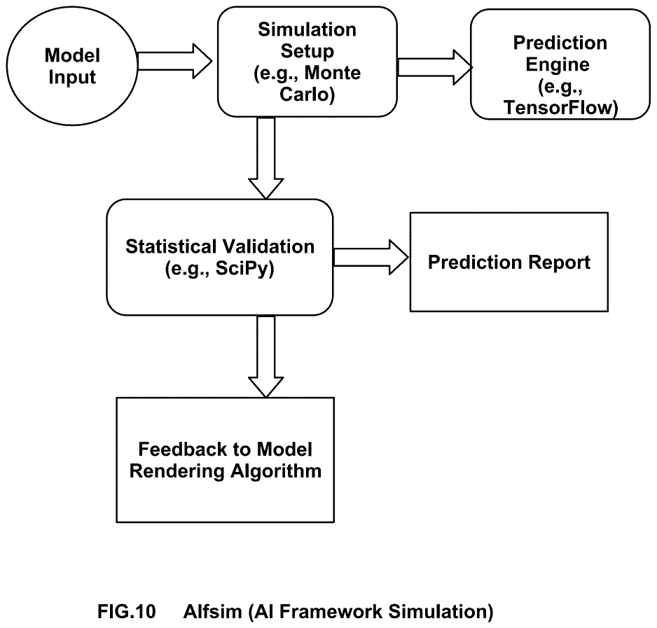

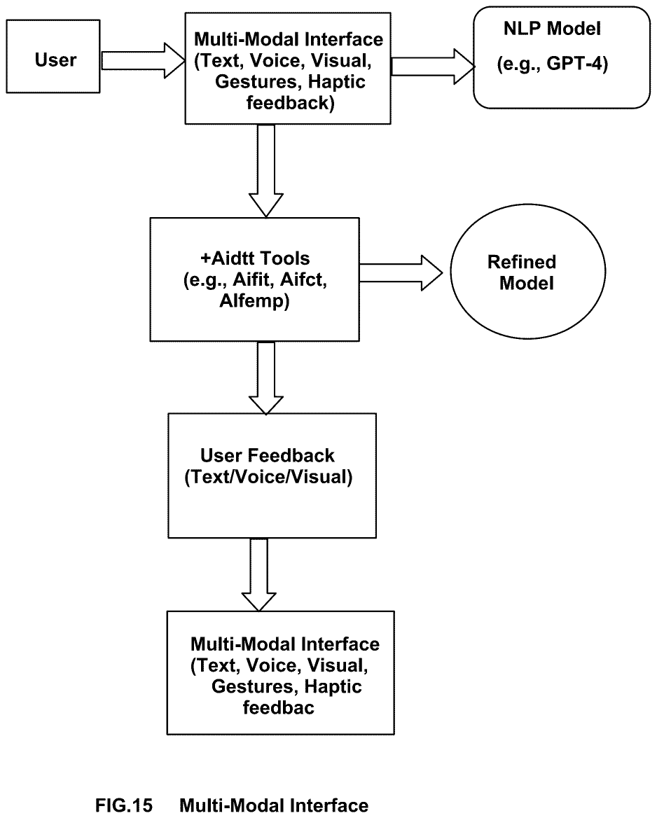

The +AIdtt system comprises the following components:
1. FRaw (Input Validation and Feedback): Validates raw inputs using NLP (e.g., SpaCy, BERT) and anomaly detection algorithms (e.g., Isolation Forest), as shown in FIG. 1.
2. Fragmentation: Breaks down validated inputs into basic theoretical constituents (e.g., axioms, hypotheses, constraints) using graph-based algorithms (e.g., NetworkX), as depicted in FIG. 2.
3. Model Rendering Algorithm: Generates initial models based on fragmented constituents using machine learning techniques (e.g., neural networks, clustering), illustrated in FIG. 3.
4. Multi-Modal Interface: Enables user interaction and recursive refinement through one or more of natural language, voice commands, visual inputs, and other interaction modalities, including but not limited to gestures, haptic feedback, and augmented reality (VR) interfaces. The interface interprets user queries using one or more interaction modalities, including but not limited to natural language processing (NLP) for text and voice inputs, computer vision for visual inputs, and other emerging interaction technologies (e.g., gestures, haptic feedback). It provides real-time feedback and triggers refinements based on user input, as demonstrated in FIG. 15.
5. Refinement Tools: Includes AIfit (framework integration, FIG. 8), Alfct (consistency testing, FIG. 4), AIfemp (empirical validation, FIG. 6), AIfcr (comparative analysis, FIG. 5), AIfsim (simulation, FIG. 10), Alfeth (ethical analysis, FIG. 7), and AIfmeta (meta-optimization, FIG. 9).

As shown in FIG. 8, the AIfit module integrates new concepts into existing theoretical frameworks, ensuring seamless compatibility and coherence across modules.

As depicted in FIG. 9, the AIfmeta module performs meta-optimization by monitoring system performance data, detecting anomalies (e.g., using Isolation Forest or Autoencoders), and providing optimization suggestions. This ensures the overall efficiency and robustness of the theory-building process.

As illustrated in FIG. 10, the AIfsim module performs simulations (e.g., using Monte Carlo methods or TensorFlow) to predict model outcomes and validate them statistically (e.g., using SciPy). The results are fed back into the Model Rendering Algorithm for further refinement, ensuring the models are robust and predictive.

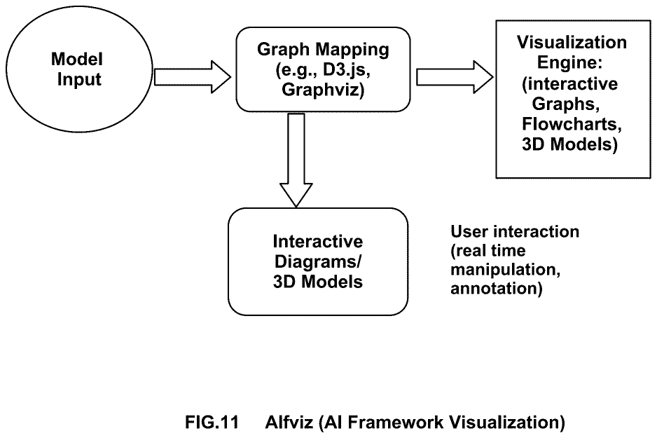

As shown in FIG. 11, the AIfviz module generates interactive visual representations of theories, including but not limited to graphs, flowcharts, or 3D models, and interactive enabling users to manipulate and annotate these visualizations in real time.

### Workflow

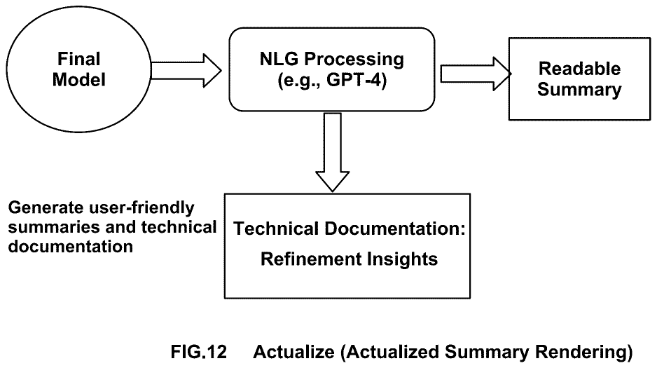

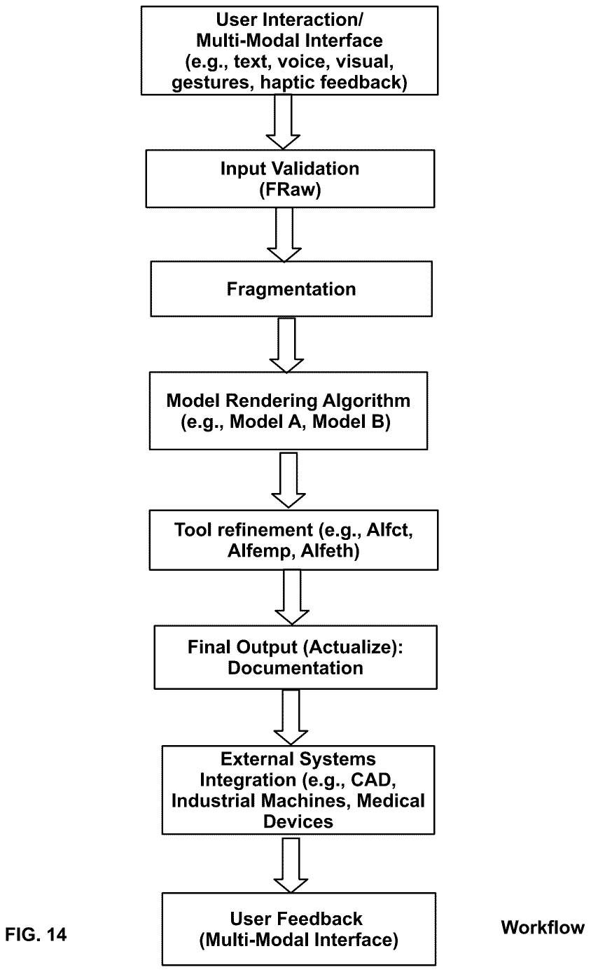

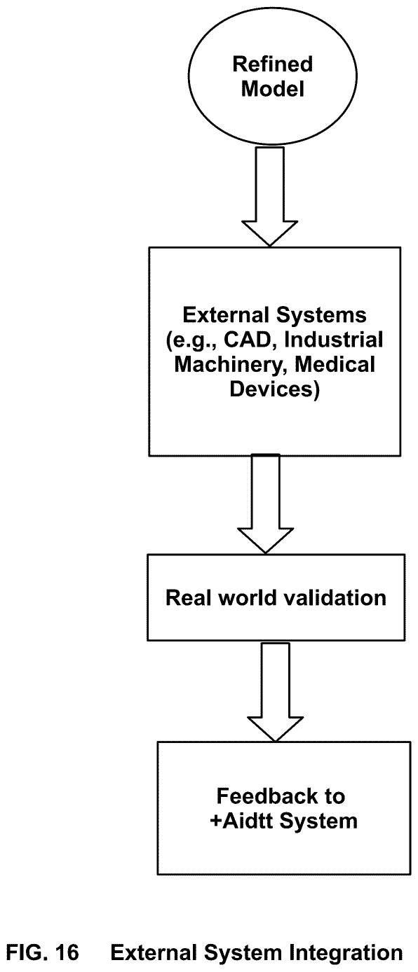

The workflow of the +AIdtt system, as depicted in FIG. 14, includes the following steps:
1. User Interaction (Multi-Modal): The user interacts with the system interface providing inputs, queries, or feedback through one or more interaction modalities, including but not limited to text, voice, visual inputs, gestures and haptic feedback.
2. Input Validation (FRaw): The chat interface sends users inputs to FRaw for validation, as shown in FIG. 1.
3. Fragmentation: Validated inputs are broken down into theoretical constituents (e.g., axioms, hypotheses, constraints), as illustrated in FIG. 2.
4. Model Rendering Algorithm: Initial models are generated based on the fragmented constituents, as depicted in FIG. 3.
5. Tool Refinement: Models are refined using tools such as AIfct (consistency testing, FIG. 4), AIfemp (empirical validation, FIG. 6), and AIfeth (ethical analysis, FIG. 7).
6. Final Output (Actualize): The refined models are summarized and documented, as shown in FIG. 12. The Actualize module (FIG. 12) generates a comprehensive summary of the refined models, including key insights, validation results, and recommendations for further refinement.
7. External System Integration: The refined models are validated against real-world data and tested for practical feasibility using external systems, including but not limited to CAD software, Industrial machines, and medical devices. The results are fed back into the system for further refinement, ensuring the models are robust and applicable in real-world scenarios, as shown in FIG. 16.
8. User Feedback (Multi-Modal Interface): The refined models are returned to the user via multi-modal interfaces, including but not limited to text, voice and visual inputs, enabling further feedback and refinement, as illustrated in FIG. 15.

This end-to-end workflow ensures a systematic and iterative approach to theory building, as visually represented in FIG. 14.

### Iterative Refinement Feedback Loop

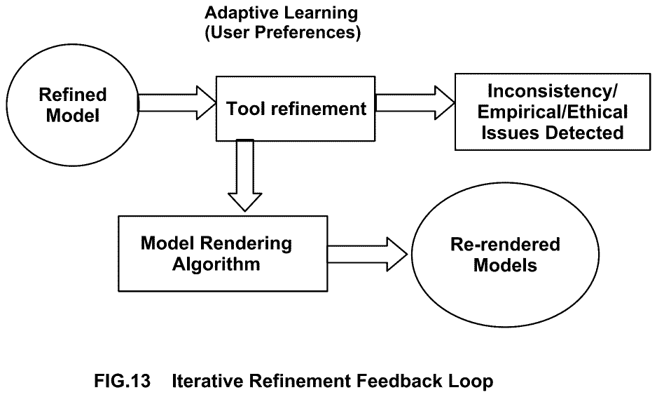

As shown in FIG. 13, the Model Rendering Algorithm interacts with the tools to refine models iteratively. If any tool identifies issues (e.g., inconsistencies, lack of empirical grounding, ethical concerns), the models are sent back to the Model Rendering Algorithm for refinement. This feedback loop ensures that the final models meet all criteria for consistency, empirical fit, and ethical soundness. Additionally, the system is configured to adapt to the user's preferences and working style over time using machine learning techniques, ensuring a more efficient and user-friendly experience with continued use. The system also enables a personalized interaction across multiple modalities, including but not limited to natural language, voice commands, visual inputs, gestures, and haptic feedback, allowing users to interact with the system in a way that best suits their needs and preferences.

The +AIdtt system is configured to integrate with a wide range of external systems, including but not limited to scientific instruments, simulation platforms, industrial machines, financial systems, medical devices, and social data repositories. This integration enables the system to validate theoretical models against real-world data, test their practical feasibility, and implement them in real-world applications. For example, in engineering, the system may connect to CAD software to test design theories; in medicine, it may integrate with electronic health records (EHRs) to validate diagnostic models; and in economics, it may analyze data from financial market APIs to test economic theories. This capability ensures that the theories generated by +AIdtt are not only logically coherent and empirically grounded but also practically applicable across disciplines.

What is claimed is:

1. A system for AI-driven theoretical testing, comprising:
a. a FRaw module configured to validate inputs using natural language processing (NLP) and anomaly detection algorithms;
b. a fragmentation module configured to break down validated inputs into basic theoretical constituents;
c. a Model Rendering Algorithm configured to generate initial models based on the fragmented constituents;
d. a plurality of refinement tools configured to iteratively refine the models, wherein the refinement tools include AIfit, AIfct, AIfemp, AIfcr, AIfsim, AIfeth, and AIfmeta;
e. a multi-modal interface configured to enable user interaction and recursive refinement through one or more of natural language, voice commands, visual inputs, and other interaction modalities, including but not limited to gestures, haptic feedback, and augmented reality (VR) interfaces. wherein the interface interprets user queries, provides real-time feedback, and triggers iterative refinement based on user input.
f. an iterative feedback loop between the refinement tools and the Model Rendering Algorithm, wherein the models are recursively refined based on feedback from the refinement tools.

2. The system of claim 1, wherein the Model Rendering Algorithm uses machine learning techniques, including neural networks, clustering decision trees, and reinforcement learning, to generate initial models.

3. The system of claim 1, wherein the refinement tools include a consistency testing module (AIfct) configured to detect and resolve logical inconsistencies in the models using formal logic systems.

4. The system of claim 1, wherein the refinement tools include an empirical validation module (AIfemp) configured to validate models against empirical data using statistical and experimental validation techniques.

5. The system of claim 1, wherein the refinement tools include a comparative analysis module (AIfcr) configured to compare different theoretical models and frameworks to identify strengths, weaknesses, and areas for improvement.

6. The system of claim 1, wherein the refinement tools include a meta-optimization module (AIfmeta) configured to monitor system performance, detect anomalies, and provide optimization suggestions to improve the efficiency and robustness of the theory-building process.

7. The system of claim 1, wherein the refinement tools include a visualization module (AIfviz) configured to generate interactive visual representations of theories, including but not limited to graphs, flowcharts, and 3D models, to enhance user understanding and interaction.

8. The system of claim 1, wherein the refinement tools include a simulation module (AIfsim) configured to predict model outcomes using techniques such as Monte Carlo methods and TensorFlow, and validate the outcomes statistically using tools such as SciPy.

9. The system of claim 1, wherein the refinement tools include an integration module (AIfit) configured to seamlessly integrate new concepts into existing theoretical frameworks, ensuring compatibility and coherence across models.

10. The system of claim 1, wherein the refinement tools include an ethical analysis module (AIfeth) configured to detect the ethical implications, and mitigate ethical issues and biases in theoretical models.

11. The system of claim 1, wherein the multi-modal interface is configured to interpret user queries using natural language processing (NLP), provide real-time feedback to the user, and trigger the iterative refinement feedback loop by sending user feedback to the Model Rendering Algorithm.

12. The system of claim 1, wherein the multi-modal interface is configured to support multi-modal interactions, including one or more of text, voice, and visual inputs, and provide context-aware responses to user queries.

13. The system of claim 1, further comprising an iterative feedback loop between the refinement tools and the Model Rendering Algorithm, wherein the models are recursively refined based on feedback from the refinement tools and user inputs, and wherein the system adapts to the user's preference and working style over time using machine learning techniques.

14. The system of claim 1, further configured to integrate with external systems, including but not limited to scientific instruments, simulation platforms, industrial machines, financial systems, medical devices, and social data repositories, enabling real-time feedback on real-world feasibility, practical implementations, and validation against empirical data.
